(19) United States
(12) Patent Application Publication
(10) Pub. No.: US 2003/0015291 A1
(43) Pub. Date: Jan. 23, 2003

(54) Semiconductor device fabrication apparatus having multi-hole angled gas injection system

(75) Inventors: Young-Suk Lee, Kyunggi-do (KR); Young-Mook Kang, Kyunggi-do (KR)

Correspondence Address: OSTROLENK FABER GERB & SOFFEN, 1180 AVENUE OF THE AMERICAS, NEW YORK, NY, 100368403

(73) Assignee: Jusung Engineering Co., Ltd.

(21) Appl. No.: 10/193,968

(22) Filed: Jul. 10, 2002

(30) Foreign Application Priority Data
Jul. 18, 2001 (KR) 43076/2001

(51) Int. Cl. C23F 1/00; C23C 16/00

(52) U.S. Cl. 156/345.33; 118/715

(57) ABSTRACT

A semiconductor device fabrication apparatus includes: a reactive chamber having a gas discharge hole and providing a reactive space therein closed against the outside; a susceptor installed inside the reactive chamber for mounting a substrate, a target of a process; and a plurality of gas injection holes arranged in a ring shape along an inner wall of the reactive chamber, wherein an outer annular passage and an inner annular passage are formed along the side wall inside the side wall of the reactive chamber, the outer annular passage and the inner annular passage are connected to each other by means of a connection passage, the outer annular passage is connected to the outside of the reactive chamber through a gas supply pipe and the inner annular passage is connected to the inside of the reactive chamber through a plurality of gas supply pipes.

### BACKGROUND OF THE INVENTION

1. Field of the Invention

The present invention relates to a semiconductor device fabrication apparatus, and more particularly, to a semiconductor device fabrication apparatus having a multi-hole angled gas injection system for injecting a gas so that the gas can be uniformly distributed in a reactive chamber.

2. Description of the Background Art

As a wafer grows to have a large diameter to heighten a production yield, a process uniformity is more degraded in a thin film deposition process or a dry etching process due to a limitation in a structure of a semiconductor device fabrication apparatus.

Such a process uniformity degradation is one of direct reasons to reduce the production yield of the semiconductor device. Thus, in order to improve the process uniformity, a semiconductor device fabrication apparatus needs to be formed in consideration of flow dynamics and geometrical aspects.

The process uniformity is much influenced depending on a method supplying a gas to the reactive chamber. This is the same in case of a semiconductor device fabrication apparatus that performs various processes by using a plasma such as a plasma enhanced chemical vapor deposition (PECVD) or an anisotropic etching.

Widely known methods for a gas supply include a showerhead type, a single injector type, a baffle type, or the like.

The showerhead type is that a showerhead with more than hundreds of injection holes is positioned at the very upper side of a wafer to inject a gas. This method is advantageous to obtain uniformity of a film. However, since the space between the showerhead and the wafer is comparatively small, a gas activation for forming a plasma slows only to degrade the thin film characteristics.

The single injector type injects a gas through one gas injector. This method is suitable to a reactive chamber structure in a dome shape, and thus, its use coverage is limited and a uniformity of a thin film is hardly obtained.

The baffle type is mainly used for an APCVD apparatus and uses a belt conveyer, and its film quality is excellent. However, it is not easy to obtain a uniformity of a film, a system itself is so complicated that it is not easy to maintain and manage it for use, and it is not easy to be adopted to an LPCVD apparatus.

### SUMMARY OF THE INVENTION

Therefore, an object of the present invention is to provide a semiconductor device fabrication apparatus that is capable of uniformly distributing a gas inside a reactive chamber by forming a gas injection system with a simple structure inside the chamber without attaching a gas injector.

To achieve these and other advantages and in accordance with the purpose of the present invention, as embodied and broadly described herein, there is provided a semiconductor device fabrication apparatus including: a reactive chamber having a gas discharge hole and providing a reactive space therein closed against the outside; a susceptor installed inside the reactive chamber for mounting a substrate, a target of a process; and a plurality of gas injection holes arranged in a ring shape along an inner wall of the reactive chamber, wherein an outer annular passage and an inner annular passage are formed along the side wall inside the side wall of the reactive chamber, the outer annular passage and the inner annular passage are connected to each other by means of a connection passage, the outer annular passage is connected to the outside of the reactive chamber through a gas supply pipe and the inner annular passage is connected to the inside of the reactive chamber through a plurality of gas supply pipes.

In the semiconductor device of the present invention, preferably, there are provided two connection passages facing each other, and a portion where the gas supply pipe and the outer annular passage meet is positioned at the middle between the connection passages.

In the semiconductor device of the present invention, a plasma electrode can be additionally provided to receive an RF power from an external source and generate a plasma within the reactive chamber, and a heating unit may be installed at an outer upper portion of the reactive chamber.

In the semiconductor device of the present invention, the gas injection holes are arranged at regular intervals and preferably have a diameter of 1 to 7 mm. The gas supply pipe can be horizontal or inclined upwardly, and if it is inclined, preferably, it has an angle of below 60°. And, it is preferred that the upper portion of the reactive chamber has a dome shape.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic view of a semiconductor device fabrication apparatus in accordance with the present invention;

FIG. 2A is a view concretely showing a gas injection system of a semiconductor device fabrication apparatus in accordance with the present invention;

FIG. 2B is a view showing a section of a portion ‘A’ of FIG. 2A;

FIG. 2C is a view showing a section of a portion ‘B’ of FIG. 2A;

FIG. 2D is a view showing a section of a portion of ‘D’ of FIG. 2A; and

FIG. 2E is a view showing cross sections of internal passages of FIG. 2A.

### DETAILED DESCRIPTION OF THE PREFERRED EMBODIMENTS

Reference will now be made in detail to the preferred embodiments of the present invention, examples of which are illustrated in the accompanying drawings.

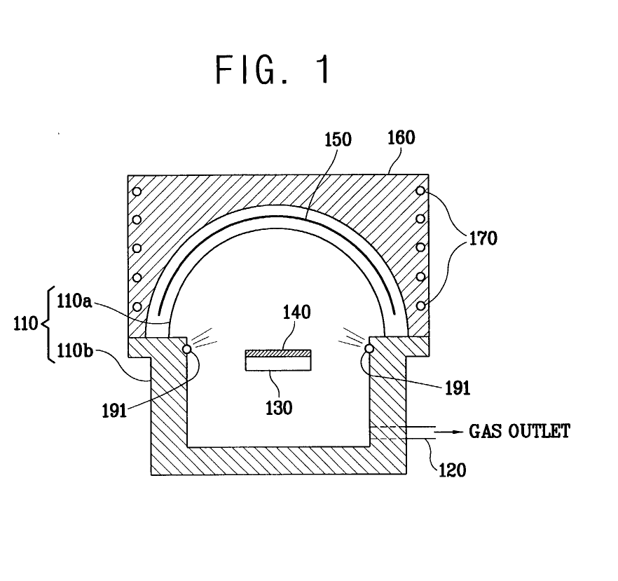

FIG. 1 is a schematic view of a semiconductor device fabrication apparatus in accordance with the present invention.

As shown in FIG. 1, a reactive chamber 110 provides a reactive space closed against outside, and a gas discharge hole 120is provided at a lower portion 110b of the chamber.

A susceptor 130 is installed within the reactive chamber 110 to mount a substrate 140, a target of a process, thereon.

A plasma electrode 150 is installed at an outer side of the upper portion 110a of the chamber 110 in order to receive an RF power from an external source and generate a plasma within the reactive chamber 110. In case of a process not using a plasma, such a plasma electrode is not necessary.

A gas is injected through the plurality of gas injection holes 191 arranged in a ring shape at the side wall of the reactive chamber 110, and this is the main characteristics of the present invention.

The upper portion of the reactive chamber 110 is preferably formed in a dome shape and made of quartz or alumina. A bell jar 160 is installed to cover an upper outer side of the reactive chamber 110 including the plasma electrode 150.

A heating unit 170 is installed inside the bell jar 160 in order to heat the inside of the reactive chamber 110.

When the gas is injected inclined upwardly through the gas injection hole 191, since the upper portion of the reactive chamber 110 has the dome shape, the injected gas is very uniformly distributed inside the reactive chamber 110.

Especially, when the gas collides with the upper portion of the reactive chamber 110, it receives heat generated from the heating unit 170 for a good activation, and thus, deposition to the substrate 140 becomes more active.

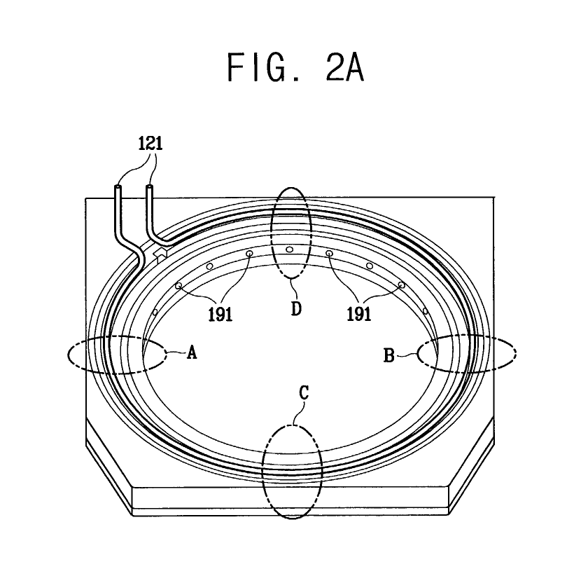

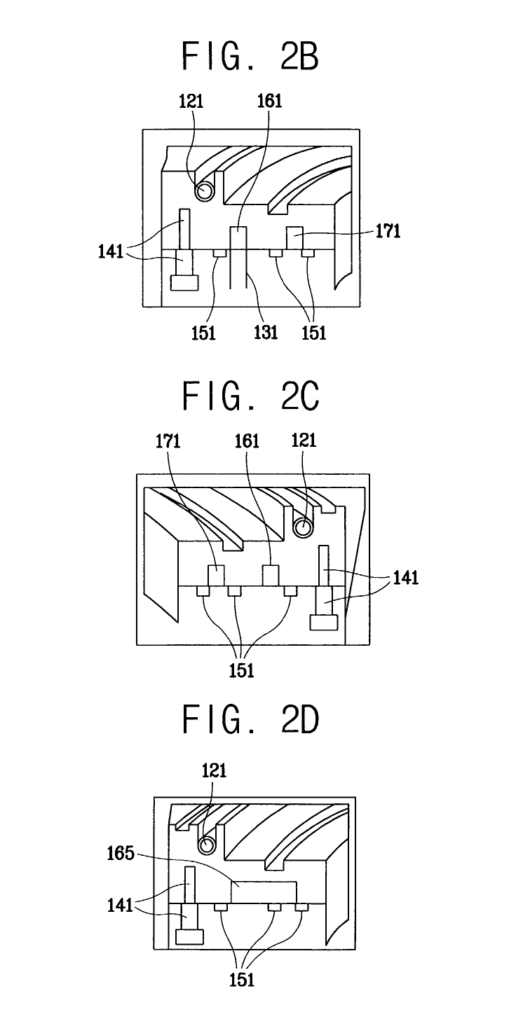

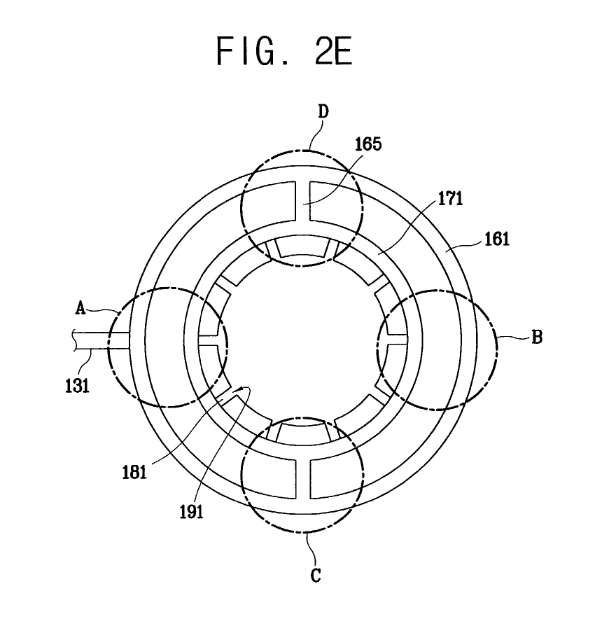

FIGS. 2A through 2E concretely show a multi-hole angled gas injection system of the semiconductor device fabrication apparatus of the present invention. FIGS. 2B through 2D illustrate each section of the portions ‘A’, ‘B’ and ‘D’ of FIG. 2A, and FIG. 2E shows cross sections of internal passages of FIG. 2A.

With reference to FIGS. 2A through 2E, an outer annular passage 161 and an inner annular passage 171 are formed inside the side wall of the reactive chamber 110 along the side wall, and the outer annular passage 161 and the inner annular passage 171 are connected to each other by a connection passage 165.

The connection passages 165 are provided facing at the portions indicated by ‘C’ and ‘D’. The position and the number of the connection passages 165 can vary according to a purpose of a system. For example, four connection passages can be formed at each middle portion of ‘A’, B’, ‘C’ and ‘D’ in FIG. 2.

The outer annular passage 161 is connected to the outside of the reactive chamber 110 through the gas supply pipe 131 of FIG. 2B.

The portion indicated by ‘A’ is a portion where the outer annular passage 161 and the gas supply pipe 131 are connected. Here, the gas supply pipe 131 comes down to the lower portion along the side wall of the reactive chamber 110 and is connected to the outside.

The portion indicated by ‘A’ is positioned at the middle portion between ‘C’ and ‘D’.

The portion indicated by ‘B’ has the same passage structure with the portion indicated by ‘A’, only without the gas supply pipe 131. However, a gas supply pipe can be possibly installed at the portion ‘B’.

The inner annular passage 171 is connected to the inside of the reactive chamber 110 through the plurality of gas supply pipes 181 as shown in FIG. 2E. Thus, a plurality of gas injection holes 171 are arranged in a ring shape inside the reactive chamber 110 along the inside wall.

The gas supply pipe 181 can be horizontal or inclined upwardly, and in this respect, the gas supply pipe 181 is preferably inclined upwardly so that a gas can be injected upwardly. The inclination of the gas supply pipe 181 is preferably at below 60°. In consideration of the relative position between the injection gas and the substrate, if the inclination angle of the gas supply pipe is greater than 60°, the injected gas can be hardly injected uniformly toward the substrate.

The gas injection holes 191 are arranged at regular intervals and have a diameter of 1 to 7 mm. The number of injection holes may vary according to the size of an apparatus and preferably can be 8 to 150.

The upper end portion of the side wall of the reactive chamber 110 as shown in FIG. 2A is to be coupled with an upper portion 110a of the chamber 110 of FIG. 1. At this combination portion, a cooling water pipe 121 is formed in a ring shape, in which cooling water flows.

The inner annular passage 171 and the outer annular passage 161 are formed such that the reactive chamber 110 is horizontally cut, an annular groove is formed at the bottom of the upper portion, and the upper portion and the lower portion are coupled by threads (141). And, in order to prevent occurrence of leakage, an o-ring 151 is inserted at the combination portion.

As so far described, the semiconductor device fabrication apparatus of the present invention has many advantages.

That is, for example, a gas can be uniformly distributed with a simple apparatus structure without a gas injector.

In addition, since the gas passage is formed double, a gas can be injected at a uniform pressure and velocity, and even if more than two types of gases are injected through the gas supply pipe 131, the gases can be sufficiently mixed in the passage. Thus, a process uniformity can be improved.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such meets and bounds are therefore intended to be embraced by the appended claims.

What is claimed is:

1. A semiconductor device fabrication apparatus comprising:
a reactive chamber having a gas discharge hole and providing a reactive space therein closed against the outside;
a susceptor installed inside the reactive chamber for mounting a substrate, a target of a process; and
a plurality of gas injection holes arranged in a ring shape along an inner wall of the reactive chamber,
wherein an outer annular passage and an inner annular passage are formed along the side wall inside the side wall of the reactive chamber, the outer annular passage and the inner annular passage are connected to each other by means of a connection passage, the outer annular passage is connected to the outside of the reactive chamber through a gas supply pipe and the inner annular passage is connected to the inside of the reactive chamber through a plurality of gas supply pipes.

2. The apparatus of claim 1, wherein there are provided two connection passages facing each other, and a portion where the gas supply pipe and the outer annular passage meet is positioned at the middle between the connection passages.

3. The apparatus of claim 1, wherein a plasma electrode is additionally provided to receive an RF power from an external source and generate a plasma within the reactive chamber, and a heating unit may be installed at an outer upper portion of the reactive chamber.

4. The apparatus of claim 1, wherein the gas injection holes are arranged at regular intervals and have a diameter of 1 to 7 mm.

5. The apparatus of claim 1, wherein the gas injection holes are 8 to 150 in number.

6. The apparatus of claim 1, wherein the gas supply pipe is formed horizontal or inclined upwardly.

7. The apparatus of claim 6, wherein the gas supply pipe is formed inclined upwardly at an angle of below 60°.

8. The apparatus of claim 1, wherein the upper portion of the reactive chamber has a dome shape.

9. The apparatus of claim 1, further comprising a heating unit installed at an outer upper portion of the reactive chamber.

10. The apparatus of claim 1, further comprising a cooling water pipe formed inside the side wall of the reactive chamber.
